(19) United States
(12) Patent Application Publication
(10) Pub. No.: US 2021/0405111 A1
(43) Pub. Date: Dec. 30, 2021

(54) TEST METHOD AND ELECTRONIC DEVICE

(71) Applicant: BAIDU ONLINE NETWORK TECHNOLOGY (BEIJING) CO., LTD., Beijing (CN)

(72) Inventors: Bingqing NI, Beijing (CN); Yimeng ZHAI, Beijing (CN); Huiting ZHANG, Beijing (CN); Yunxuan DU, Beijing (CN); Feifei LU, Beijing (CN); Yuanqi ZHANG, Beijing (CN)

(73) Assignee: BAIDU ONLINE NETWORK TECHNOLOGY (BEIJING) CO., LTD.

(21) Appl. No.: 17/111,302

(22) Filed: Dec. 3, 2020

(30) Foreign Application Priority Data
Jun. 29, 2020 (CN) 202010602034.3

(51) Int. Cl. G01R 31/28

(52) U.S. Cl. CPC G01R 31/2834

(57) ABSTRACT

The present disclosure discloses a test method and an electronic device. The method includes: displaying a test interface including controls of a plurality of test actions in response to a test request for a target terminal, and obtaining a control of a target test action selected by a user from the controls of the plurality of test actions; matching operations of respective application objects on the target terminal with the control of the target test action, obtaining a plurality of candidate application objects successfully matched with the control of the target test action, and displaying identification information of the plurality of candidate application objects on the test interface; and obtaining a target identifier selected by the user from the identification information of the plurality of candidate application objects, and controlling a target application object corresponding to the target identifier to perform the target test action for testing.

### CROSS-REFERENCE TO RELATED APPLICATION

This application is based upon and claims priority to and benefits of Chinese Patent Application Serial No. 202010602034.3, filed the State Intellectual Property Office of P. R. China on Jun. 29, 2020, the entire content of which is incorporated herein by reference.

### FIELD

Embodiments of the present disclosure relate to a field of computer technologies and a field of computer foreground technologies, and particularly to a test method and an electronic device, which may be applied to applications such as a performance test or an application object test of a terminal device based on artificial intelligence.

### BACKGROUND

In order to ensure a service quality of an application on a computer, a computer program is generally configured to test the application. Presently, a test method generally employed is writing script codes to implement a test.

### SUMMARY

According to a first aspect, a test method is provided. The method includes: displaying a test interface including controls of a plurality of test actions in response to a test request for a target terminal, and obtaining a control of a target test action selected by a user from the controls of the plurality of test actions; matching operations of respective application objects on the target terminal with the control of the target test action, obtaining a plurality of candidate application objects successfully matched with the control of the target test action, and displaying identification information of the plurality of candidate application objects on the test interface; and obtaining a target identifier selected by the user from the identification information of the plurality of candidate application objects, and controlling a target application object corresponding to the target identifier to perform the target test action for testing.

According to a second aspect, an electronic device is provided. The electronic device includes: at least one processor and a memory. The memory is communicatively coupled to the at least one processor. The memory is configured to store instructions executed by the at least one processor. When the instructions are executed by the at least one processor, the at least one processor is caused to implement the test method according to the first aspect.

According to a fourth aspect, a non-transitory computer readable storage medium is provided. The non-transitory computer readable storage medium has computer instructions stored thereon. The computer instructions are configured to enable a computer to perform the test method according to the first aspect.

It should be understood that, description in Summary of the present disclosure does not aim to limit a key or important feature in embodiments of the present disclosure, and does not used to limit the scope of the present disclosure. Other features of the present disclosure will be easily understood by following descriptions.

### BRIEF DESCRIPTION OF THE DRAWINGS

The accompanying drawings are used for better understanding the solution and do not constitute a limitation of the present disclosure.

FIG. 1 is a flow chart illustrating a test method according to a first embodiment of the present disclosure.

FIG. 2 is a schematic diagram illustrating a test interface according to a second embodiment of the present disclosure.

FIG. 3-1 is a schematic diagram illustrating a display scene of identification information of candidate application objects according to a third embodiment of the present disclosure.

FIG. 3-2 is a schematic diagram illustrating a display scene of identification information of candidate application objects according to a fourth embodiment of the present disclosure.

FIG. 4 is a flow chart illustrating a test method according to a fifth embodiment of the present disclosure.

FIG. 5 is a block diagram illustrating a test apparatus according to a sixth embodiment of the present disclosure.

FIG. 6 is a block diagram illustrating a test apparatus according to a seventh embodiment of the present disclosure.

FIG. 7 is a block diagram illustrating an electronic device capable of implementing a test method according to an eight embodiment of the present disclosure.

### DETAILED DESCRIPTION

Description will be made below to exemplary embodiments of the present disclosure with reference to accompanying drawings, which includes various details of embodiments of the present disclosure to facilitate understanding and should be regarded as merely examples. Therefore, it should be recognized by the skilled in the art that various changes and modifications may be made to the embodiments described herein without departing from the scope and spirit of the present disclosure. Meanwhile, for clarity and conciseness, descriptions for well-known functions and structures are omitted in the following description.

In order to ensure a service quality of an application on a computer, a computer program is generally configured to test the application. Presently, a test method generally employed is writing script codes to implement a test. However, since a logic of test codes of a test script is complex, a functional tester may not quickly master automatic script writing. As there is a strong coupling between the test codes and a test framework, when a large number of scripts are increased, a code base becomes redundant, and it is difficult to maintain the script and the test framework, thus a maintenance cost is high. Thus, the present disclosure provides a test method and a test apparatus.

Description will be made below to a test method and a test apparatus in embodiments of the present disclosure with reference to accompanying drawings.

The test method in embodiments of the present disclosure may be applied to a terminal independent of a target terminal to be tested. The terminal independent of the target terminal may be a computer or the like. In this way, testing for a test object of the target terminal may be implemented on a test interface of the terminal independent of the target terminal, and a performance test and an application object test of a terminal device based on artificial intelligence may also be implemented. The test belongs to a field of computer test technologies in a field of computer technologies, which provides a new test idea. A test operation in embodiments of the present disclosure may be implemented simply by performing simple operations on the test interface, thereby reducing a test cost. A test control on the test interface has a high independence, which reduces a maintenance cost.

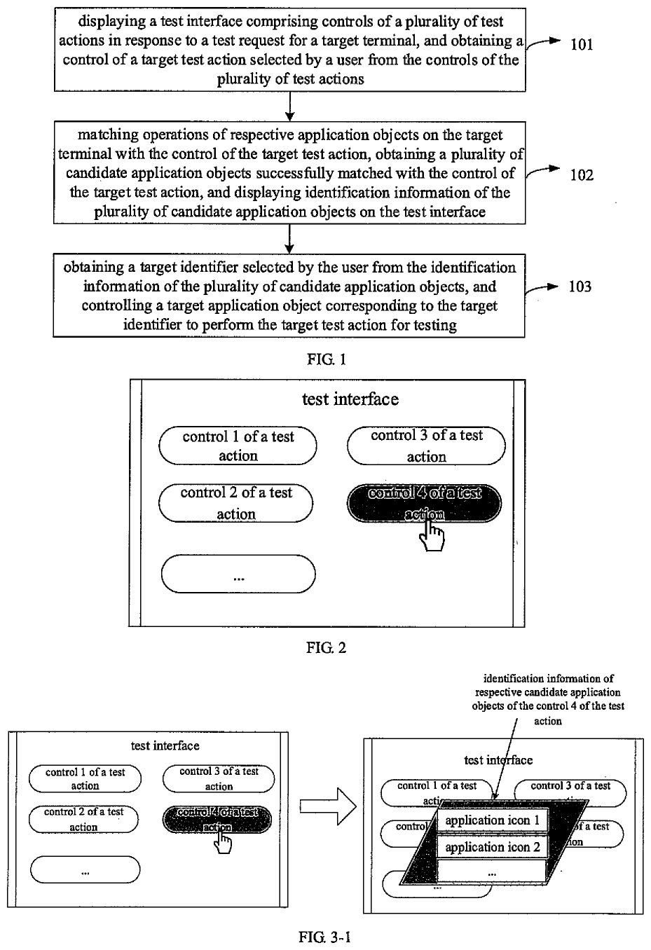

FIG. 1 is a flow chart illustrating a test method according to a first embodiment of the present disclosure. The method may be performed by a test apparatus provided in embodiments of the present disclosure, and may also be performed by an electronic device provided in embodiments of the present disclosure. The electronic device may include, but be not limited to, a terminal device such as a desktop computer and a tablet computer, and a server. Description will be made below to the present disclosure by taking that the test apparatus provided in embodiments of the present disclosure performs the test method provided in embodiments of the present disclosure as an example, but may not be taken as a limitation of the present disclosure.

As illustrated in FIG. 1, the test method may include the following.

At block 101, a test interface including controls of multiple test actions is displayed in response to a test request for a target terminal, and a control of a target test action selected by a user from the controls of the multiple test actions is obtained.

The test request in this embodiment may be sent from the target terminal or from a background server. When the test request is sent from the background server, the target terminal to be tested is determined based on a terminal identifier sent from the background server.

In an embodiment, as illustrated in FIG. 2, the test interface including the controls of the multiple test actions is displayed after the test request is received. A control of each test action corresponds to integrated execution codes of the test action, such as, execution codes of a start action or execution codes of an operation of sending a file. Codes of controls of different test actions are not associated with each other, which ensures that the control of each test action may run independently, thereby improving reusability, avoiding coupling between a test framework and test codes, and facilitating maintenance.

It should be noted that the integrated execution codes of each test action in this embodiment only includes the execution codes of the test action, and a parameter of a test object may be understood as blank. Thereby, in this embodiment, a corresponding test action may be performed on the test object simply by binding the test object for the control of the test action and supplementing the blank.

In an embodiment of the present disclosure, referring to FIG. 2, the control of the target test action selected by the user from the controls of the multiple test actions is obtained.

In an embodiment of the present disclosure, the test request may carry detailed key information of the test action. The target test action may be determined by extracting the key information. For example, when the test request includes “turn on this application”, the key information of the test action is “turn on”, and the control of the target test action matching with the test action “turn on” is obtained.

At block 102, operations of respective application objects on the target terminal are matched with the control of the target test action, multiple candidate application objects successfully matched with the control of the target test action are obtained, and identification information of the multiple candidate application objects is displayed on the test interface.

Not each application object is able to perform a test action of a test control. For example, when the test action is “pay”, it is obvious that some application objects is not able to perform the test action. Therefore, in some embodiments, the operations of respective application objects on the target terminal are matched with the control of the target test action, and the multiple candidate application objects successfully matched with the control of the target test action are obtained.

In an embodiment of the present disclosure, a preset database may be queried to determine a test action corresponding to the control of the target test action. The test action is matched with an action of each application object. An application object successfully matched is determined as a candidate application object.

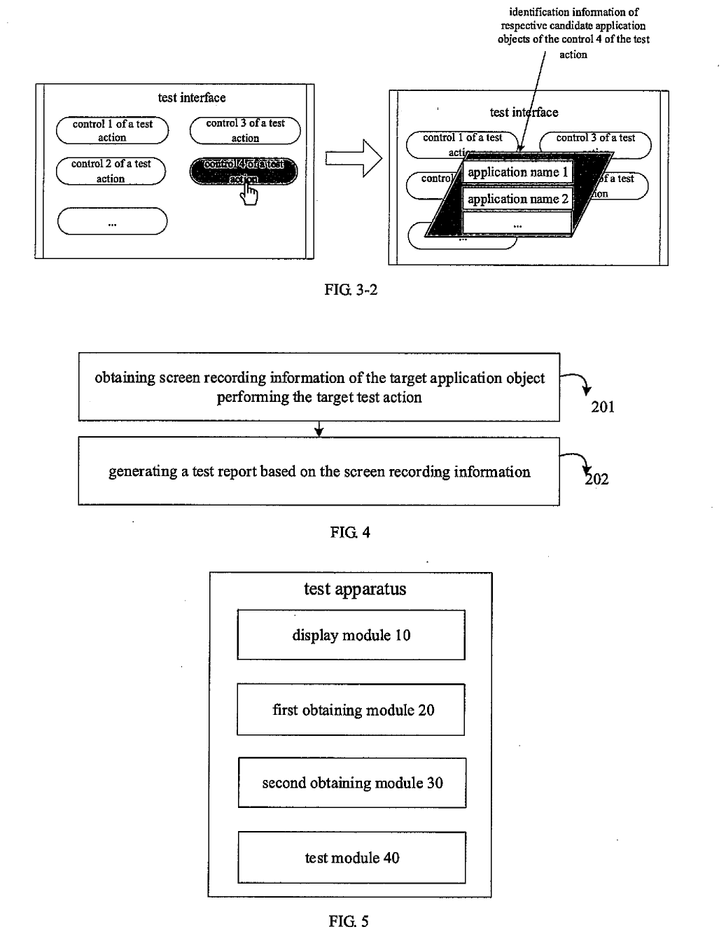

The identification information of each candidate application object is displayed on the test interface. As illustrated in FIG. 34, the identification information may be an application icon of an application object. As illustrated in FIG. 3-2, the identification information may be an application name of an application object. The identification information may be displayed in a form of a pop-up window.

At block 103, a target identifier selected by the user from the identification information of the multiple candidate application objects is obtained, and a target application object corresponding to the target identifier is controlled to perform the target test action for testing.

In an embodiment, the target identifier selected by the user from the identification information of respective candidate application objects is obtained. For example, a target icon selected by the user from application icons of the multiple candidate test objects is obtained, and the target icon is determined as the target application object.

In an embodiment of the present disclosure, the control of each test action is integrated with the execution codes of the test action. Therefore, after the target application object is determined, a test instruction corresponding to the target test action and the target application object may be generated. That is, an object parameter of the target application object is written into a test object parameter of the execution codes to generate test codes that may be performed by the target terminal. The test instruction carries the test codes. Then, the test instruction is sent to the target terminal, such that the target terminal controls the target application object to perform the target test action.

For example, the test codes in the test instruction are start codes for the WeChat application. The target terminal executes the test codes to start the WeChat application when receiving the test instruction.

In an actual implementing procedure, in order to avoid disturbing a normal use for the target application object on the target terminal, a current running interface of the target application object is obtained before the test instruction is sent to the target terminal, and the test instruction is sent only when it is determined that the current running interface does not belong to a preset running interface. The preset running interface is an interface which is not suitable to be disturbed and set by the user or calibrated by the system, such as a video interface or a payment interface.

In an embodiment of the present disclosure, there may be multiple target test actions for the same target application object, so the multiple target test actions are packaged into one single file. The test request includes the single file. The target test actions in the single file is performed on the target application object after the single file is parsed by the target terminal.

In this way, with the test method according to embodiments of the present disclosure, various kinds of supported actions of UI (user interface) automation are integrated into an interface of controls of test actions, such that an automatic test is completely separated from the codes, and a novice may easily get started. The test codes generated by a developer through interface operations may be encapsulated in a single file. When the test codes are executed, the target terminal may read the single file and automatically parse the single file for execution. Through this procedure, the test may be completely decoupled from tool codes.

In conclusion, with the test method of this embodiment, the test interface including the controls of the multiple test actions is displayed in response to the test request for the target terminal. The control of the target test action selected by the user from the controls of the multiple test actions is obtained. The operations of respective application objects on the target terminal are matched with the control of the target test action. The multiple candidate application objects successfully matched with the control of the target test action are obtained. The identification information of the multiple candidate application objects is displayed on the test interface. Then, the target identifier selected by the user from the identification information of the multiple candidate application objects is obtained. The target application object corresponding to the target identifier is controlled to perform the target test action for testing. In this way, a test difficulty and a maintenance cost are reduced, and a test efficiency is improved.

Based on the above embodiments, when the target application object corresponding to the target identifier is controlled to perform the target test action for testing, a test result is obtained to generate a test report, which facilitates to subsequent upgrade of the application object.

As illustrated in FIG. 4, after the action at block 103, the method also includes the followings.

At block 201, screen recording information of the target application object performing the target test action is obtained.

In an embodiment, the screen recording information of the target application object performing the target test action is recorded. The screen recording information includes interface information when the target test object performs the target test action.

At block 202, a test report is generated based on the screen recording information.

In an embodiment, the interface information of the target application object in the screen recording information may be extracted. The test information of the target application object performing the target test action is analyzed based on the interface information, to generate the test report. The test information includes a duration for performing the target test action and information indicating whether the interface display is normal after the target test action is performed. For example, when the target test action is a “start” action, corresponding test information is information indicating whether the interface is switched to a default home page after the target application object performs the “start” action, and information indicating whether there is an interface such as “a splash screen” during starting a home page.

In conclusion, with the test method of embodiments of the present disclosure, the test report is generated based on the screen recording information, thus a way for generating the test report is simplified, and the efficiency for generating the test report is improved.

According to embodiments of the present disclosure, the present disclosure also provides a test apparatus.

FIG. 5 is a block diagram illustrating a test apparatus according to a sixth embodiment of the present disclosure. As illustrated in FIG. 5, the test apparatus includes: a display module 10, a first obtaining module 20, a second obtaining module 30, and a test module 40.

The display module 10 is configured to display a test interface including controls of multiple test actions in response to a test request for a target terminal.

The first obtaining module 20 is configured to obtain a control of a target test action selected by a user from the controls of the multiple test actions.

The second obtaining module 30 is configured to match operations of respective application objects on the target terminal with the control of the target test action, and to obtain multiple candidate application objects successfully matched with the control of the target test action.

The display module 10 is further configured to display identification information of the plurality of candidate application objects on the test interface.

The test module 40 is configured to obtain a target identifier selected by the user from the identification information of the multiple candidate application objects, and to control a target application object corresponding to the target identifier to perform the target test action for testing.

In a possible implementation of embodiments of the present disclosure, the second obtaining module 30 is also configured to: query a preset database to determine a test action corresponding to the control of the target test action; and match the test action with an action of each application object, and determine an application object successfully matched as a candidate application object.

In a possible implementation of embodiments of the present disclosure, the test module 40 is also configured to: generate a test instruction corresponding to the target test action and the target application object; and send the test instruction to the target terminal, such that the target terminal controls the target application object to perform the target test action.

It should be noted that, the above description for embodiments of the test method is also applicable to the test apparatus of this embodiment, and has the similar principle, which is not be elaborated here.

In conclusion, with the test apparatus of this embodiment, the test interface including the controls of the multiple test actions is displayed in response to the test request for the target terminal. The control of the target test action selected by the user from the controls of the multiple test actions are obtained. The operations of respective application objects on the target terminal are matched with the control of the target test action. The multiple candidate application objects successfully matched with the control of the target test action are obtained. The identification information of the multiple candidate application objects is displayed on the test interface. Then, the target identifier selected by the user from the identification information of the multiple candidate application objects is obtained. The target application object corresponding to the target identifier is controlled to perform the target test action for testing. In this way, a test difficulty and a maintenance cost are reduced, and a test efficiency is improved.

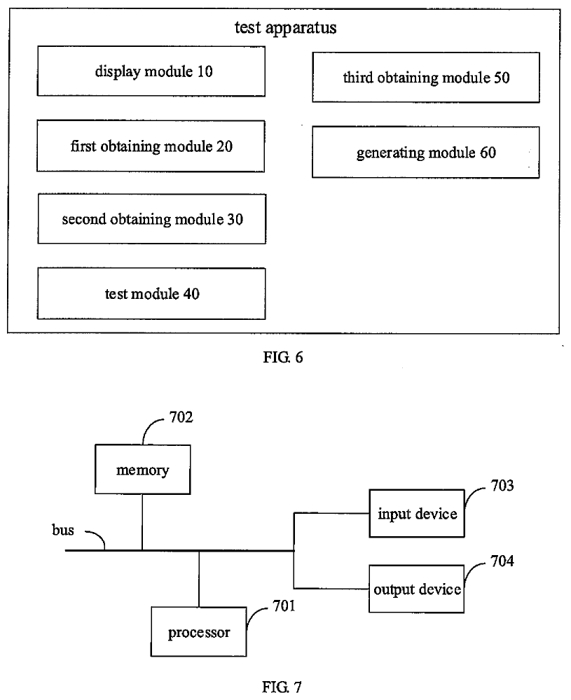

In some embodiments of the present disclosure, as illustrated in FIG. 6, on the basis of FIG. 5, the test apparatus also includes: a third obtaining module 50 and a generating module 60.

The third obtaining module 50 is configured to obtain screen recording information of the target application object performing the target test action.

The generating module 60 is configured to generate a test report based on the screen recording information.

It should be noted that, the above description for embodiments of the test method is also applicable to the test apparatus of this embodiment, and has the similar principle, which is not be elaborated here.

In conclusion, with the test apparatus of embodiments of the present disclosure, based on the screen recording information, a way for generating the test report is simplified, and the efficiency for generating the test report is improved.

According to embodiments of the present disclosure, the present disclosure also provides an electronic device and a readable storage medium.

As illustrated in FIG. 7, FIG. 7 is a block diagram illustrating an electronic device capable of implementing a test method according to embodiments of the present disclosure. The electronic device aims to represent various forms of digital computers, such as a laptop computer, a desktop computer, a workstation, a personal digital assistant, a server, a blade server, a mainframe computer and other suitable computer. The electronic device may also represent various forms of mobile devices, such as personal digital processing, a cellular phone, a smart phone, a wearable device and other similar computing device. The components, connections and relationships of the components, and functions of the components illustrated herein are merely examples, and are not intended to limit the implementation of the present disclosure described and/or claimed herein.

As illustrated in FIG. 7, the electronic device includes: one or more processors 701, a memory 702, and interfaces for connecting various components, including a high-speed interface and a low-speed interface. Various components are connected to each other via different buses, and may be mounted on a common main board or in other ways as required. The processor may process instructions executed within the electronic device, including instructions stored in or on the memory to display graphical information of the GUI (graphical user interface) on an external input/output device (such as a display device coupled to an interface). In other implementations, multiple processors and/or multiple buses may be used together with multiple memories if desired. Similarly, multiple electronic devices may be connected, and each device provides some necessary operations (for example, as a server array, a group of blade servers, or a multiprocessor system). In FIG. 7, a processor 701 is taken as an example.

The memory 702 is a non-transitory computer readable storage medium provided by the present disclosure. The memory is configured to store instructions executable by at least one processor, to enable the at least one processor to perform the test method provided by the present disclosure. The non-transitory computer readable storage medium provided by the present disclosure is configured to store computer instructions. The computer instructions are configured to enable a computer to perform the test method provided by the present disclosure.

As the non-transitory computer readable storage medium, the memory 702 may be configured to store non-transitory software programs, non-transitory computer executable programs and modules, such as program instructions/module (such as the display module 10, the first obtaining module 20, the second obtaining module 30 and the test module 40 illustrated in FIG. 5) corresponding to the test method according to embodiments of the present disclosure. The processor 701 is configured to execute various functional applications and data processing of the server by operating non-transitory software programs, instructions and modules stored in the memory 702, that is, implements the test method according to the above method embodiments.

The memory 702 may include a storage program region and a storage data region. The storage program region may store an application required by an operating system and at least one function. The storage data region may store data created according to predicted usage of the electronic device based on the semantic representation. In addition, the memory 702 may include a high-speed random access memory, and may also include a non-transitory memory, such as at least one disk memory device, a flash memory device, or other non-transitory solid-state memory device. In some embodiments, the memory 702 may optionally include memories remotely located to the processor 701, and these remote memories may be connected to the electronic device via a network. Examples of the above network include, but are not limited to, an Internet, an intranet, a local area network, a mobile communication network and combinations thereof.

The electronic device capable of implementing the test method may also include: an input device 703 and an output device 704. The processor 701, the memory 702, the input device 703, and the output device 704 may be connected via a bus or in other means. In FIG. 7, the bus is taken as an example.

The input device 703 may receive inputted digital or character information, and generate key signal input related to user setting and function control of the electronic device capable of implementing the test method, such as a touch screen, a keypad, a mouse, a track pad, a touch pad, an indicator stick, one or more mouse buttons, a trackball, a joystick and other input device. The output device 704 may include a display device, an auxiliary lighting device (e.g., LED), a haptic feedback device (e.g., a vibration motor), and the like. The display device may include, but be not limited to, a liquid crystal display (LCD), a light emitting diode (LED) display, and a plasma display. In some embodiments, the display device may be the touch screen.

The various implementations of the system and technologies described herein may be implemented in a digital electronic circuit system, an integrated circuit system, an application specific ASIC (application specific integrated circuit), a computer hardware, a firmware, a software, and/or combinations thereof. These various implementations may include: being implemented in one or more computer programs. The one or more computer programs may be executed and/or interpreted on a programmable system including at least one programmable processor. The programmable processor may be a special purpose or general purpose programmable processor, may receive data and instructions from a storage system, at least one input device, and at least one output device, and may transmit data and the instructions to the storage system, the at least one input device, and the at least one output device.

These computing programs (also called programs, software, software applications, or codes) include machine instructions of programmable processors, and may be implemented by utilizing high-level procedures and/or object-oriented programming languages, and/or assembly/machine languages. As used herein, the terms “machine readable medium” and “computer readable medium” refer to any computer program product, device, and/or apparatus (such as, a magnetic disk, an optical disk, a memory, a programmable logic device (PLD)) for providing machine instructions and/or data to a programmable processor, including a machine readable medium that receives machine instructions as a machine readable signal. The term “machine readable signal” refers to any signal for providing the machine instructions and/or data to the programmable processor.

To provide interaction with a user, the system and technologies described herein may be implemented on a computer. The computer has a display device (such as, a CRT (cathode ray tube) or a LCD (liquid crystal display) monitor) for displaying information to the user, a keyboard and a pointing device (such as, a mouse or a trackball), through which the user may provide the input to the computer. Other types of devices may also be configured to provide interaction with the user. For example, the feedback provided to the user may be any form of sensory feedback (such as, visual feedback, auditory feedback, or tactile feedback), and the input from the user may be received in any form (including acoustic input, voice input or tactile input).

The system and technologies described herein may be implemented in a computing system including a background component (such as, a data server), a computing system including a middleware component (such as, an application server), or a computing system including a front-end component (such as, a user computer having a graphical user interface or a web browser through which the user may interact with embodiments of the system and technologies described herein), or a computing system including any combination of such background component, the middleware components and the front-end component. Components of the system may be connected to each other via digital data communication in any form or medium (such as, a communication network). Examples of the communication network include a local area network (LAN), a wide area networks (WAN), and the Internet.

The computer system may include a client and a server. The client and the server are generally remote from each other and generally interact via the communication network. A relationship between the client and the server is generated by computer programs operated on a corresponding computer and having a client-server relationship with each other.

It should be understood that, steps may be reordered, added or deleted by utilizing flows in the various forms illustrated above. For example, the steps described in the present disclosure may be executed in parallel, sequentially or in different orders, so long as desired results of the technical solution disclosed in the present disclosure may be achieved, there is no limitation here.

The above detailed implementations do not limit the protection scope of the present disclosure. It should be understood by the skilled in the art that various modifications, combinations, sub-combinations and substitutions may be made based on design requirements and other factors. Any modification, equivalent substitution and improvement made within the spirit and the principle of the present disclosure shall be included in the protection scope of present disclosure.

What is claimed is:

1. A test method, comprising:
displaying a test interface comprising controls of a plurality of test actions in response to a test request for a target terminal, and obtaining a control of a target test action selected by a user from the controls of the plurality of test actions;
matching operations of respective application objects on the target terminal with the control of the target test action, obtaining a plurality of candidate application objects successfully matched with the control of the target test action, and displaying identification information of the plurality of candidate application objects on the test interface; and
obtaining a target identifier selected by the user from the identification information of the plurality of candidate application objects, and controlling a target application object corresponding to the target identifier to perform the target test action for testing.

2. The method of claim 1, further comprising:
obtaining screen recording information of the target application object performing the target test action; and
generating a test report based on the screen recording information.

3. The method of claim 1, wherein matching operations of respective application objects on the target terminal with the control of the target test action and obtaining the plurality of candidate application objects successfully matched with the control of the target test action comprises:
querying a preset database to determine a test action corresponding to the control of the target test action; and
matching the test action with an action of each application object, and determining an application object successfully matched as a candidate application object.

4. The method of claim 2, wherein matching operations of respective application objects on the target terminal with the control of the target test action and obtaining the plurality of candidate application objects successfully matched with the control of the target test action comprises:
querying a preset database to determine a test action corresponding to the control of the target test action; and
matching the test action with an action of each application object, and determining an application object successfully matched as a candidate application object.

5. The method of claim 1, wherein controlling the target application object corresponding to the target identifier to perform the target test action for testing comprises:
generating a test instruction corresponding to the target test action and the target application object; and
sending the test instruction to the target terminal, such that the target terminal controls the target application object to perform the target teat action.

6. The method of claim 2, wherein controlling the target application object corresponding to the target identifier to perform the target test action for testing comprises:
generating a test instruction corresponding to the target test action and the target application object; and
sending the test instruction to the target terminal, such that the target terminal controls the target application object to perform the target test action.

7. The method of claim 5, before sending the test instruction to the target terminal, further comprising:
obtaining a current running interface of the target application object; and
determining that the current running interface does not belong to a preset running interface.

8. An electronic device, comprising:
at least one processor; and
a memory, communicatively coupled to the at least one processor,
wherein the memory is configured to store instructions executable by the at least one processor, and when the instructions are executed by the at least one processor, the at least one processor is caused to implement a test method, the method comprising:
displaying a test interface comprising controls of a plurality of test actions in response to a test request for a target terminal, and obtaining a control of a target test action selected by a user from the controls of the plurality of test actions;
matching operations of respective application objects on the target terminal with the control of the target test action, obtaining a plurality of candidate application objects successfully matched with the control of the target test action, and displaying identification information of the plurality of candidate application objects on the test interface; and
obtaining a target identifier selected by the user from the identification information of the plurality of candidate application objects, and controlling a target application object corresponding to the target identifier to perform the target test action for testing.

9. The electronic device of claim 8, wherein the method further comprises:
obtaining screen recording information of the target application object performing the target test action; and
generating a test report based on the screen recording information.

10. The electronic device of claim 8, wherein matching operations of respective application objects on the target terminal with the control of the target test action and obtaining the plurality of candidate application objects successfully matched with the control of the target test action comprises:
querying a preset database to determine a test action corresponding to the control of the target test action; and
matching the test action with an action of each application object, and determining an application object successfully matched as a candidate application object.

11. The electronic device of claim 9, wherein matching operations of respective application objects on the target terminal with the control of the target test action and obtaining the plurality of candidate application objects successfully matched with the control of the target test action comprises:
querying a preset database to determine a test action corresponding to the control of the target test action; and
matching the test action with an action of each application object, and determining an application object successfully matched as a candidate application object.

12. The electronic device of claim 8, wherein controlling the target application object corresponding to the target identifier to perform the target test action for testing comprises:
generating a test instruction corresponding to the target test action and the target application object; and
sending the test instruction to the target terminal, such that the target terminal controls the target application object to perform the target test action.

13. The electronic device of claim 9, wherein controlling the target application object corresponding to the target identifier to perform the target test action for testing comprises:
generating a test instruction corresponding to the target test action and the target application object; and
sending the test instruction to the target terminal, such that the target terminal controls the target application object to perform the target test action.

14. The electronic device of claim 12, wherein, before sending the test instruction to the target terminal, the method further comprises:
obtaining a current running interface of the target application object; and
determining that the current running interface does not belong to a preset running interface.

15. A non-transitory computer readable storage medium having computer instructions stored thereon, wherein the computer instructions are configured to cause a computer to perform a test method, the method comprising:
displaying a test interface comprising controls of a plurality of test actions in response to a test request for a target terminal, and obtaining a control of a target test action selected by a user from the controls of the plurality of test actions;
matching operations of respective application objects on the target terminal with the control of the target test action, obtaining a plurality of candidate application objects successfully matched with the control of the target test action, and displaying identification information of the plurality of candidate application objects on the test interface; and
obtaining a target identifier selected by the user from the identification information of the plurality of candidate application objects, and controlling a target application object corresponding to the target identifier to perform the target test action for testing.

16. The storage medium of claim 15, wherein the method further comprises:
obtaining screen recording information of the target application object performing the target test action; and
generating a test report based on the screen recording information.

17. The storage medium of claim 15, wherein matching operations of respective application objects on the target terminal with the control of the target test action and obtaining the plurality of candidate application objects successfully matched with the control of the target test action comprises:
querying a preset database to determine a test action corresponding to the control of the target test action; and
matching the test action with an action of each application object, and determining an application object successfully matched as a candidate application object.

18. The storage medium of claim 16, wherein matching operations of respective application objects on the target terminal with the control of the target test action and obtaining the plurality of candidate application objects successfully matched with the control of the target test action comprises:
querying a preset database to determine a test action corresponding to the control of the target test action; and
matching the test action with an action of each application object, and determining an application object successfully matched as a candidate application object.

19. The storage medium of claim 15, wherein controlling the target application object corresponding to the target identifier to perform the target test action for testing comprises:
generating a test instruction corresponding to the target test action and the target application object; and
sending the test instruction to the target terminal, such that the target terminal controls the target application object to perform the target test action.

20. The storage medium of claim 19, wherein, before sending the test instruction to the target terminal, the method further comprises:
obtaining a current running interface of the target application object; and
determining that the current running interface does not belong to a preset running interface.
